(19) United States
(12) Patent Application Publication
(10) Pub. No.: US 2026/0164894 A1
(43) Pub. Date: Jun. 11, 2026

(54) DISPLAY APPARATUS AND MANUFACTURING METHOD OF DISPLAY APPARATUS

(71) Applicant: LG DISPLAY CO., LTD., Seoul (KR)

(72) Inventors: Jinhwa Shin, Paju-si (KR); Jongmin Jang, Paju-si (KR); HanSaem Kang, Paju-si (KR)

(73) Assignee: LG DISPLAY CO., LTD., Seoul (KR)

(21) Appl. No.: 19/292,366

(22) Filed: Aug. 6, 2025

(30) Foreign Application Priority Data
Dec. 9, 2024 (KR) 10-2024-0181525

(51) Int. Cl. H10H 29/80; H10H 29/01; H10H 29/37; H10H 29/855

(52) U.S. Cl. CPC H10H 29/8325; H10H 29/012; H10H 29/37; H10H 29/8323; H10H 29/8552; H10H 29/882

(57) ABSTRACT

A display apparatus can include a bank disposed on a substrate, a first electrode disposed on the bank, a light-emitting device disposed on the first electrode, and a second electrode disposed on the light-emitting device. The light-emitting device includes an anode electrode disposed on the first electrode, an intermediate layer disposed on the anode electrode, and a cathode electrode disposed on the intermediate layer. The anode electrode includes a first anode electrode disposed on the first electrode, a second anode electrode disposed on the first anode electrode, and an inorganic reflective layer disposed between the first anode electrode and the second anode electrode, extending along a side surface of the intermediate layer to surround the side surface of the intermediate layer, and having at least one hole for electrical connection between the first and second anode electrodes.

### CROSS-REFERENCE TO RELATED APPLICATION

This application claims priority to Korean Patent Application No. 10-2024-0181525, filed on Dec. 9, 2024 in the Republic of Korea, which is hereby expressly incorporated by reference for all purposes as if fully set forth herein into the present application.

### BACKGROUND

### Field

Embodiments of the present disclosure relate to a display apparatus and a manufacturing method of the display apparatus.

### Discussion of the Related Art

Display apparatuses are applied to various electronic devices such as TVs, mobile phones, laptops, and tablets. Display apparatuses can include organic light-emitting displays (OLEDs) that emit light by themselves, or liquid crystal displays (LCDs) that require a separate light source.

Recently, display apparatuses including light-emitting devices (e.g., light emitting diodes (LEDs)) have been attracting attention as the next-generation display apparatuses. Since the light-emitting devices are formed of inorganic materials rather than organic materials, they can achieve faster lighting speeds, higher luminous efficiency, and the ability to display images with high brightness, compared to the liquid crystal displays and organic light-emitting displays.

### SUMMARY OF THE DISCLOSURE

Embodiments of the present disclosure can provide a display apparatus having a structure that enhances light emission efficiency by reducing the amount of light which may be lost inside the display panel among the amount of light emitted from a light-emitting device within the display panel and by increasing the amount of light emitted to the outside of the display panel.

Embodiments of the present disclosure can provide a display apparatus that improves the reliability of a light-emitting device.

Embodiments of the present disclosure can provide a display apparatus that increases the lifetime of organic materials around the light-emitting device by blocking side light of the light-emitting device within the display panel.

Embodiments of the present disclosure can provide a display apparatus that improves the viewing angle of a display panel.

Embodiments of the present disclosure can provide a low-power display apparatus capable of achieving a desired luminance with reduced power consumption by enhancing light emission efficiency.

The objects of the embodiments of the present disclosure are not limited to those described herein, and other objects not mentioned will be clearly understood by those skilled in the art from the description below.

Embodiments of the present disclosure can provide a display apparatus comprising a substrate, a bank disposed on the substrate, a first electrode disposed on the bank, a light-emitting device disposed on the first electrode, and a second electrode disposed on the light-emitting device. The light-emitting device can comprise an anode electrode disposed on the first electrode, an intermediate layer disposed on the anode electrode, and a cathode electrode disposed on the intermediate layer. The anode electrode can comprise a first anode electrode disposed on the first electrode, a second anode electrode disposed on the first anode electrode, and an inorganic reflective layer disposed between the first anode electrode and the second anode electrode, extending along a side surface of the intermediate layer to surround the side surface of the intermediate layer, and having at least one hole for electrical connection between the first and second anode electrodes.

Embodiments of the present disclosure can provide a method of manufacturing a display apparatus, the method comprising disposing a bank on a substrate, disposing a first electrode on the bank, disposing a light-emitting device on the first electrode, and disposing a second electrode on the light-emitting device. The light-emitting device can comprise an anode electrode disposed on the first electrode, an intermediate layer disposed on the anode electrode, and a cathode electrode disposed on the intermediate layer. The anode electrode can comprise a first anode electrode disposed on the first electrode, a second anode electrode disposed on the first anode electrode, and an inorganic reflective layer disposed between the first anode electrode and the second anode electrode, extending along a side surface of the intermediate layer to surround the side surface of the intermediate layer, and having at least one hole for electrical connection between the first and second anode electrodes.

According to embodiments of the present disclosure, it can be possible to provide a display apparatus having a structure that enhances light emission efficiency by reducing the amount of light which may be lost inside the display panel among the amount of light emitted from a light-emitting device within the display panel and by increasing the amount of light emitted to the outside of the display panel.

According to embodiments of the present disclosure, it can be possible to provide a display apparatus having a structure that enhances light emission efficiency by including a side light reflection structure.

According to embodiments of the present disclosure, it can be possible to provide a display apparatus that improves the viewing angle of a panel through a side and bottom reflection structure of the light-emitting device.

According to embodiments of the present disclosure, it can be possible to provide a low-power display apparatus capable of achieving a desired luminance with reduced power consumption by enhancing light emission efficiency.

The effects of the embodiments of the present disclosure are not limited to those mentioned above, and other effects not mentioned will be clearly understood by those skilled in the art from the description of the claims.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present disclosure.

FIG. 1 illustrates a display apparatus according to embodiments of the present disclosure.

FIG. 2 illustrates a sub-pixel of a display panel according to embodiments of the present disclosure.

FIG. 3 is a cross-sectional view of a display panel according to embodiments of the present disclosure.

FIG. 4 to FIG. 10 illustrate manufacturing processes of a display panel of a display apparatus according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa. In addition, the term “surrounding” include at least one of a complete surrounding and a partial surrounding.

Various embodiments of the present disclosure will be described in detail with reference to the accompanying drawings. All the components of each display apparatus/device according to all embodiments of the present disclosure are operatively coupled and configured.

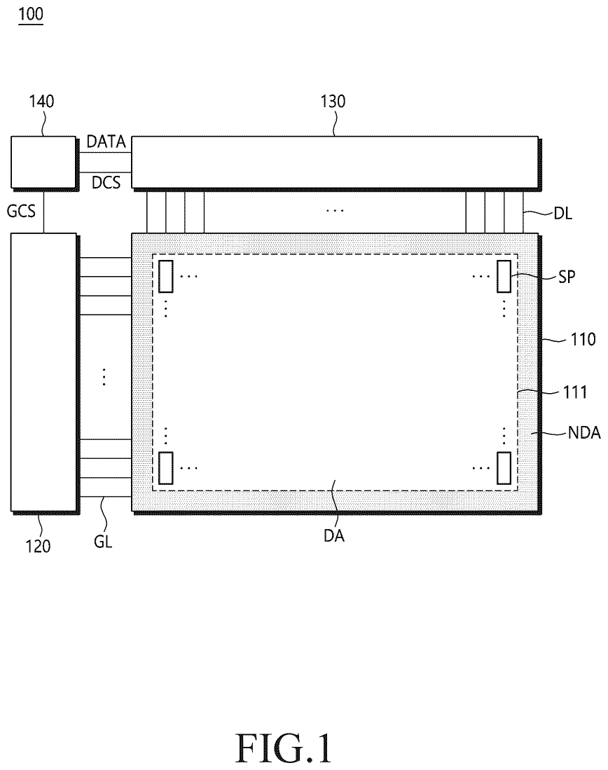

FIG. 1 illustrates a display apparatus 100 according to embodiments of the present disclosure.

Referring to FIG. 1, the display apparatus 100 can include a display panel 110, a gate driving circuit 120, a data driving circuit 130, and a controller 140, among other elements.

The display panel 110 can include a display area DA where an image is displayed and a non-display area NDA where an image is not displayed. The non-display area NDA can surround the display area DA entirely or only in part(s).

The display panel 110 can include a substrate 111, a plurality of sub-pixels SP disposed on the substrate 111, and various types of signal lines for driving the plurality of sub-pixels SP. The plurality of sub-pixels SP can be disposed in the display area DA.

The various types of signal lines can include a plurality of data lines DL for transmitting data signals (also referred to as data voltages or image signals) and a plurality of gate lines GL for transmitting gate signals (also referred to as scan signals). The plurality of data lines DL and the plurality of gate lines GL can intersect with each other.

Each of the plurality of data lines DL can be disposed extending in a first direction. Each of the plurality of gate lines GL can be disposed extending in a second direction. Here, the first direction can correspond to a column direction, and the second direction can correspond to a row direction. Alternatively, the first direction can correspond to a row direction, and the second direction can correspond to a column direction. In the following description, for convenience of explanation, it is assumed that the data lines DL are disposed in the column direction and the gate lines GL are disposed in the row direction.

The data driving circuit 130 can be a circuit for driving the data lines DL and can output data signals to the data lines DL. The gate driving circuit 120 can be a circuit for driving the gate lines GL and can output gate signals to the gate lines GL. The controller 140 can be a device for controlling the data driving circuit 130 and the gate driving circuit 120, and can control the driving timings for the data lines DL and the gate lines GL.

The controller 140 can supply a data driving control signal DCS to the data driving circuit 130 to control the data driving circuit 130 and can supply a gate driving control signal GCS to the gate driving circuit 120 to control the gate driving circuit 120.

The data driving circuit 130 can supply data signals DATA to the plurality of data lines DL under the control of the driving timing by the controller 140. The data driving circuit 130 can receive digital image data from the controller 140, convert the received image data into analog data signals, and output the analog data signals to the plurality of data lines DL.

The gate driving circuit 120 can supply gate signals to the plurality of gate lines GL under the timing control of the controller 140. The gate driving circuit 120 can receive a first gate voltage corresponding to a turn-on level voltage and a second gate voltage corresponding to a turn-off level voltage, together with various gate driving control signals (e.g., start signals, reset signals, etc.), generate gate signals, and supply the generated gate signals to the plurality of gate lines GL.

For example, the data driving circuit 130 can be connected to the display panel 110 using a Tape Automated Bonding (TAB) method, or can be connected to bonding pads of the display panel 110 using a Chip On Glass (COG) method or a Chip On Panel (COP) method, or can be implemented using a Chip On Film (COF) method and connected to the display panel 110. Hereinafter, for convenience of description, it is assumed that the data driving circuit 130 is connected to the display panel 110 by a Chip On Film (COF) type.

The gate driving circuit 120 can be connected to the display panel 110 using a Tape Automated Bonding (TAB) method, or connected to the bonding pads of the display panel 110 using a Chip On Glass (COG) method or a Chip On Panel (COP) method, or connected to the display panel 110 according to a Chip On Film (COF) method. Alternatively, the gate driving circuit 120 can be disposed in a non-active area or an active area of the display panel 110 in a Gate In Panel (GIP) type.

Meanwhile, at least one of the data driving circuit 130 and the gate driving circuit 120 can be disposed in the active area of the display panel 110. For example, at least one of the data driving circuit 130 and the gate driving circuit 120 can be disposed without overlapping the sub-pixels SP, or the entire or a portion of at least one of the data driving circuit 130 and the gate driving circuit 120 can be disposed overlapping the sub-pixels SP.

The data driving circuit 130 can be connected to one side (e.g., an upper side or a lower side) of the display panel 110. Depending on the driving method or panel design method, the data driving circuit 130 can be connected to both sides (e.g., upper and lower sides) of the display panel 110, or can be connected to two or more sides among the four sides (e.g., upper, lower, left, and right sides) of the display panel 110.

The gate driving circuit 120 can be connected to one side (e.g., a left side or a right side) of the display panel 110. Depending on the driving method or panel design method, the gate driving circuit 120 can be connected to both sides (e.g., left and right sides) of the display panel 110, or can be connected to two or more sides among the four sides (e.g., upper, lower, left, and right sides) of the display panel 110.

The controller 140 can be implemented as a component separate from the data driving circuit 130 or can be integrated together with the data driving circuit 130 as an integrated circuit. The controller 140 can be a timing controller commonly used in display technologies or a control device that includes a timing controller and further performs other control functions. Alternatively, the controller 140 can be a different control device or a circuit within a control device. The controller 140 can be implemented using various circuits or electronic components such as an Integrated Circuit (IC), a Field Programmable Gate Array (FPGA), an Application Specific Integrated Circuit (ASIC), or a processor.

The controller 140 can be mounted on a printed circuit board or a flexible printed circuit and can be electrically connected to the data driving circuit 130 and the gate driving circuit 120 through the printed circuit board or the flexible printed circuit. The controller 140 can transmit and receive signals to and from the data driving circuit 130 according to one or more predetermined interfaces. For example, the interface can include a Low Voltage Differential Signaling (LVDS) interface, an Embedded Panel Interface (EPI), or a Serial Peripheral Interface (SPI).

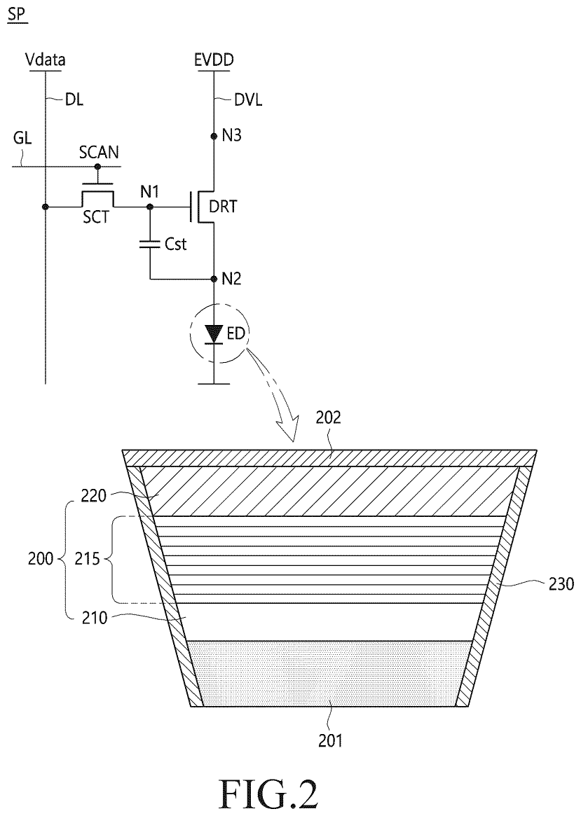

FIG. 2 illustrates a sub-pixel of the display panel 110 according to embodiments of the present disclosure. Each of one or more of the plurality of sub-pixels of the display panel 100 can have the configuration shown in FIG. 2 or other configurations.

Referring to FIG. 2, the sub-pixel SP disposed in the display panel 110 of the display apparatus 100 according to embodiments of the present disclosure can include one or more transistors and a capacitor, and can include a light-emitting device ED. For example, the sub-pixel SP can include a driving transistor DRT, a scan transistor SCT, a storage capacitor Cst, and a light-emitting device ED.

The driving transistor DRT can be a transistor for driving the light-emitting device ED and can include a first node N1, a second node N2, and a third node N3.

The first node N1 of the driving transistor DRT can be a gate node of the driving transistor DRT and can be electrically connected to a source node or a drain node of the scan transistor SCT. The second node N2 of the driving transistor DRT can be a source node or a drain node of the driving transistor DRT and can also be electrically connected to a pixel electrode PE of the light-emitting device ED. The third node N3 of the driving transistor DRT can be electrically connected to a driving voltage line DVL that supplies a driving voltage EVDD.

The scan transistor SCT can be controlled by a scan pulse SCAN, which is a type of gate signal, and can be connected between the first node N1 of the driving transistor DRT and a data line DL. In other words, the scan transistor SCT can be turned on or off according to the scan pulse SCAN supplied from a scan line SCL, which is a type of gate line GL, thereby controlling the connection between the data line DL and the first node N1 of the driving transistor DRT.

The scan transistor SCT can be turned on by a scan pulse SCAN having a turn-on level voltage, thereby delivering a data signal Vdata supplied from the data line DL to the first node N1 of the driving transistor DRT.

Here, if the scan transistor SCT is an n-type transistor, the turn-on level voltage of the scan pulse SCAN can be a high-level voltage. If the scan transistor SCT is a p-type transistor, the turn-on level voltage of the scan pulse SCAN can be a low-level voltage.

The storage capacitor Cst can be connected between the first node N1 and the second node N2 of the driving transistor DRT. The storage capacitor Cst can store a charge corresponding to the voltage difference between both terminals and maintain the voltage difference for a predetermined frame time. Accordingly, the corresponding sub-pixel SP can emit light during the predetermined frame time.

The structure of the light-emitting device ED in the display panel 110 according to embodiments of the present disclosure is illustrated.

Each of the plurality of light-emitting devices ED disposed in the display panel 110 according to embodiments of the present disclosure can be an inorganic-based light-emitting diode (LED). For example, each of the plurality of light-emitting devices ED can be a micro light-emitting diode (micro LED). As one example, each of the plurality of light-emitting devices ED can be a vertical-type light-emitting diode.

Each of the plurality of light-emitting devices ED can include an anode electrode 201, a first semiconductor layer 210, an active layer 215, a second semiconductor layer 220, and a cathode electrode 202. The first semiconductor layer, the active layer, and the second semiconductor layer can be collectively referred to as an intermediate layer 200.

For example, the anode electrode 201 can include at least one selected from gold (Au), copper (Cu), tin (Sn), titanium (Ti), aluminum (Al), silver (Ag), chromium (Cr), nickel (Ni), platinum (Pt), titanium (Ti), and titanium tungsten (TiW).

For example, the cathode electrode 202 can be made of a transparent conductive material (TCO) such as indium tin oxide (ITO), zinc oxide (ZnO), or indium zinc oxide (IZO), which can transmit light.

The first semiconductor layer 210 can be disposed on the anode electrode 201. For example, the first semiconductor layer 210 can be a p-type semiconductor and can include a semiconductor material having a chemical formula of AlₓGa_{y}In_{1-x-y}N (0≤x≤1, 0≤y≤1, 0≤x+y≤1), but is not limited thereto. For example, the semiconductor material included in the first semiconductor layer 210 can be at least one selected from p-type doped AlGaInN, GaN, AlGaN, InGaN, AlN, and InN, but is not limited thereto. The first semiconductor layer 210 can be doped with a p-type dopant, and the p-type dopant can include Mg, Zn, Ca, Se, Ba, or the like, but is not limited thereto. For example, the first semiconductor layer 210 can be p-GaN doped with p-type Mg, but is not limited thereto.

Meanwhile, the light-emitting device ED can further include an electron blocking layer disposed on the first semiconductor layer 210. The electron blocking layer can be a layer for suppressing or preventing an excessive amount of electrons from flowing into the active layer 215. For example, the electron blocking layer can be p-AlGaN doped with p-type Mg, but is not limited thereto. The electron blocking layer can be omitted.

The active layer 215 can be disposed on the first semiconductor layer 210 or the electron blocking layer. The active layer 215 can emit light by the recombination of electron-hole pairs according to electrical signals applied through the first semiconductor layer 210 and the second semiconductor layer 220. The active layer 215 can emit one of a first color light, a second color light, and a third color light. For example, the first color light can be red light, the second color light can be green light, and the third color light can be blue light.

The active layer 215 can include a material having a single or multiple quantum well (MQW) structure. If the active layer 215 includes a multiple quantum well structure, it can have a structure in which a plurality of well layers and barrier layers are alternately stacked. Here, the well layer can be formed of indium gallium nitride (InGaN), and the barrier layer can be formed of gallium nitride (GaN) or aluminum gallium nitride (AlGaN), but is not limited thereto.

Alternatively, the active layer 215 can have a structure in which semiconductor materials having a large bandgap energy and semiconductor materials having a small bandgap energy are alternately stacked, or can include different group III to group V semiconductor materials depending on the wavelength band of the emitted light. For example, if the semiconductor material included in the active layer 215 contains indium, the color of the emitted light can vary depending on the indium content. For example, as the indium content increases, the light emitted can shift toward a longer wavelength band. For instance, when the indium content is about 15%, blue wavelength light can be emitted, when about 25%, green wavelength light can be emitted, and when about 35% or more, red wavelength light can be emitted.

Meanwhile, the light-emitting device ED can further include a superlattice layer disposed on the active layer 215. The superlattice layer can be a layer for relieving stress between the second semiconductor layer 220 and the active layer 215. For example, the superlattice layer can be formed of InGaN or GaN. The superlattice layer can be omitted.

The second semiconductor layer 220 can be disposed on the active layer 215 or the superlattice layer. For example, the second semiconductor layer 220 can be an n-type semiconductor and can include a semiconductor material having a chemical formula of AlₓGa_{y}In_{1-x-y}N (0≤x≤1, 0≤y≤1, 0≤x+y≤1), but is not limited thereto. For example, the semiconductor material included in the second semiconductor layer 220 can be at least one selected from n-type doped AlGaInN, GaN, AlGaN, InGaN, AlN, and InN, but is not limited thereto. For example, the second semiconductor layer 220 can be doped with an n-type dopant, and the n-type dopant can include Si, Ge, Sn, or the like, but is not limited thereto. For example, the second semiconductor layer 220 can be n-GaN doped with n-type Si, but is not limited thereto.

The cathode electrode 202 can be disposed on the second semiconductor layer 220.

The light-emitting device ED can further include an insulating layer 230 for protecting the components of the light-emitting device ED. The insulating layer 230 can also be referred to as a protective layer or an encapsulation layer.

The insulating layer 230 can be disposed surrounding the side surfaces of the intermediate layer 200. For example, the insulating layer 230 can be disposed along the side surfaces of the first semiconductor layer 210, the second semiconductor layer 220, and the active layer 215.

The insulating layer 230 can be disposed surrounding all or a portion of the side surface of the anode electrode 201. The insulating layer 230 can be extended from the side surface of the anode electrode 201 to the rear surface of the anode electrode 201.

In one example, the anode electrode 201 can be a single electrode.

In another example, the anode electrode 201 can be formed of multiple electrodes. For example, when the anode electrode 201 is formed of multiple electrodes, it can include a first anode electrode and a second anode electrode disposed on the first anode electrode.

When the anode electrode 201 includes the first anode electrode and the second anode electrode, the insulating layer 230 can be disposed between the first anode electrode and the second anode electrode and can include at least one hole. The first anode electrode and the second anode electrode can be connected through the at least one hole formed in the insulating layer 230.

The insulating layer 230 can also be disposed along the side surfaces of the first semiconductor layer 210, the second semiconductor layer 220, and the active layer 215.

For example, the insulating layer 230 can be formed of any one selected from a silicon oxide film (SiOₓ), a silicon nitride film (SiNₓ), or an aluminum oxide film (Al₂O₃), or a stacked structure thereof.

The display panel 110 of the display apparatus 100 according to embodiments of the present disclosure can have a structure that reduces the amount of light loss inside the display panel 110 among the amount of light emitted from the light-emitting device and increases the amount of light emitted outwardly toward the light-emitting direction for image display, thereby improving the light emission efficiency.

Hereinafter, the structure for improving light emission efficiency of the display panel 110 of the display apparatus 100 according to embodiments of the present disclosure will be described.

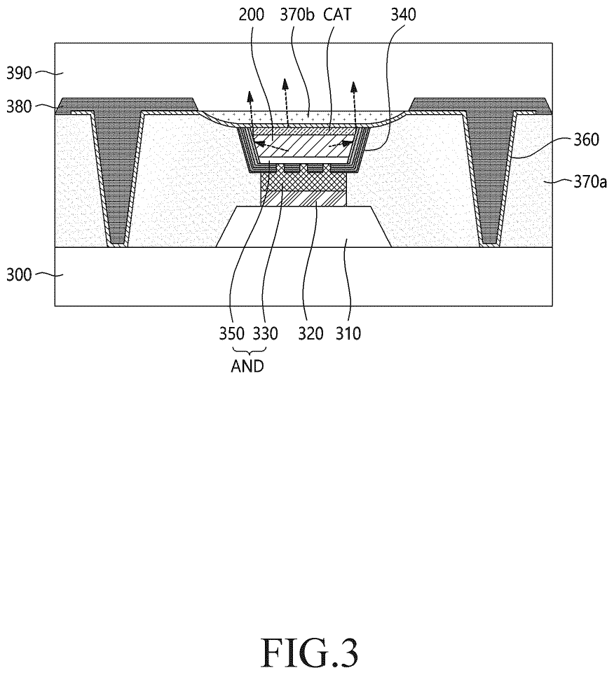

FIG. 3 is a cross-sectional view illustrating a light emission efficiency improvement structure of the display panel 110 according to embodiments of the present disclosure.

Referring to FIG. 3, the display panel 110 of the display apparatus 100 according to embodiments of the present disclosure can include a substrate 300, a bank 310 disposed on the substrate 300, a first electrode 320 disposed on the bank 310, a light-emitting device ED disposed on the first electrode 320, and a second electrode 360 disposed on the light-emitting device ED.

The first electrode 320 can include at least one selected from indium, tin, and an alloy of indium and tin.

The light-emitting device ED can include an anode electrode AND disposed on the first electrode 320, an intermediate layer 200 disposed on the anode electrode AND, and a cathode electrode CAT disposed on the intermediate layer 200.

The anode electrode AND can include a first anode electrode 330 disposed on and electrically connected to the first electrode 320, and a second anode electrode 350 disposed on and electrically connected to the first anode electrode 330.

The light-emitting device ED can further include an inorganic reflective layer 340 disposed between the first anode electrode 330 and the second anode electrode 350.

The inorganic reflective layer 340 can be disposed surrounding the side surface of the intermediate layer 200 while extending along the side surface of the intermediate layer 200. In particular, the inorganic reflective layer 340 can cover the side surface of the active layer included in the intermediate layer 200.

Since the inorganic reflective layer 340 is disposed surrounding the side surface of the intermediate layer 200, light emitted from the active layer inside the intermediate layer 200 can be reflected on the inner surface of the inorganic reflective layer 340 and emitted forward. As a result, the light extraction efficiency of the display panel 110 can be improved, and the image quality can also be enhanced. Here, the light extraction efficiency can refer to the ratio of the light emitted from the light-emitting device ED that is emitted to the outside of the display panel 110.

As described above, the inorganic reflective layer 340 can be extended and disposed between the first anode electrode 330 and the second anode electrode 350. For example, the first anode electrode 330 can be disposed under the inorganic reflective layer 340, and the second anode electrode 350 can be disposed on the inorganic reflective layer 340.

Since the inorganic reflective layer 340 is also disposed below the second anode electrode 350, light emitted downward from the active layer in the intermediate layer 200 can be reflected by the inorganic reflective layer 340 located below the second anode electrode 350 and emitted forward. As a result, the light extraction efficiency of the display panel 110 can be further improved.

The inorganic reflective layer 340 can have at least one hole for electrical connection between the first anode electrode 330 and the second anode electrode 350. The first anode electrode 330 and the second anode electrode 350 can be connected through the at least one hole formed in the inorganic reflective layer 340.

The inorganic reflective layer 340 can extend along the side surfaces of the second anode electrode 350 and the cathode electrode CAT and surround the side surfaces of the second anode electrode 350 and the cathode electrode CAT.

The size of the second anode electrode 350 can be smaller than that of the cathode electrode CAT. Accordingly, the angle between the inner surface and the bottom surface of the inorganic reflective layer 340 can be an obtuse angle. Thus, more light emitted from the active layer of the intermediate layer 200 can be emitted outside the display panel 110, further improving the light extraction efficiency of the display panel 110.

For example, the first anode electrode 330 can include a metal such as gold. The second anode electrode 350 can include a transparent electrode. At least a portion of the first anode electrode 330 can be electrically connected to the second anode electrode 350. At least a portion of the first anode electrode 330 may not be bonded to the second anode electrode 350.

According to embodiments of the present disclosure, the first electrode 320 and the first anode electrode 330 can be electrically connected through eutectic bonding. For example, when the first electrode 320 is made of indium and the first anode electrode 330 of the light-emitting device ED is made of gold, the first electrode 320 and the first anode electrode 330 can be bonded by applying heat and pressure during the transfer process of the light-emitting device ED. Through eutectic bonding, the first electrode 320 can be bonded to the first anode electrode 330 without a separate adhesive. For example, the first electrode 320 can be made of indium (In), tin (Sn), or an alloy thereof, but embodiments of the present disclosure are not limited thereto. The first electrode 320 can be a bonding pad or a joining pad, but embodiments of the present disclosure are not limited thereto.

The first anode electrode 330 can include a connection portion inserted inside the hole of the inorganic reflective layer 340.

The inorganic reflective layer 340 (Distributed Bragg Reflectors) can be formed of a plurality of inorganic layers. For example, the inorganic reflective layer can be a multilayer mirror composed of two or more materials having different refractive indices. In one example, each of the two or more materials can have a refractive index of 5 to 50. The inorganic reflective layer 340 can be non-conductive.

The display panel 110 according to embodiments of the present disclosure can further include a first window 370a surrounding the side surfaces of the bank 310 and the light-emitting device ED, and a second window 370b disposed on the second electrode 360.

For example, the first window 370a can be disposed to cover the bank 310 and the light-emitting device ED in the area of the sub-pixel SP. The first window 370a can cover the region between the bank 310 and the light-emitting device ED.

The first window 370a may not include light scattering particles. The first window 370a can be composed of an organic insulating material, but embodiments of the present disclosure are not limited thereto.

The second electrode 360 can be disposed on the first window 370a.

The second electrode 360 can be disposed between the first window 370a and the second window 370b.

The second electrode 360 can be disposed between the first window 370a and the black matrix 380 and can extend along the side surface and the bottom inside the hole of the first window.

The second electrode 360 can be disposed under the black matrix 380 along the contact hole of the first window 370a.

The second window 370b can include light scattering particles. The second window 370b can include an organic insulating material in which fine particles are dispersed, but embodiments of the present disclosure are not limited thereto. For example, the second window 370b can be composed of siloxane in which fine metal particles such as titanium dioxide (TiO₂) particles are dispersed, but embodiments of the present disclosure are not limited thereto.

According to embodiments of the present disclosure, light from the light-emitting device ED can be scattered by fine particles dispersed in the second window 370b and emitted to the outside of the display apparatus 100. Accordingly, the second window 370b can uniformly mix the light emitted from the light-emitting device ED and further improve the luminance uniformity of the display apparatus 100. In addition, by scattering light through the plurality of fine particles, the light extraction of the display apparatus 100 can be improved, and thus, the display apparatus 100 can be driven with lower power.

The second window 370b can be formed of a material different from that of the first window 370a, but embodiments of the present disclosure are not limited thereto. For example, the second window 370b can include fine particles, and the first window 370a may not include fine particles. In another example, the second window 370b can be formed of the same material as the first window 370a.

The thickness of the second window 370b can be smaller than that of the first window 370a. When viewed in a plane, the region where the first window 370a is disposed can include a recess formed below the upper surface of the second window 370b.

The display panel 110 according to embodiments of the present disclosure can further include a black matrix 380 disposed on the first window 370a and the second electrode 360. The black matrix 380 can fill the contact hole of the first window 370a. Since the black matrix 380 is configured to cover the display area, it can reduce the color mixing of light from the plurality of sub-pixels and the reflection of external light.

For example, the black matrix 380 can be composed of an opaque material, but embodiments of the present disclosure are not limited thereto. For example, the black matrix 380 can be an organic insulating material to which a black pigment or a black dye is added, but embodiments of the present disclosure are not limited thereto.

The black matrix 380 may not overlap the light-emitting device ED.

At least a portion of the black matrix 380 can overlap the second electrode 360.

The first window 370a can have a hole surrounding the light-emitting device ED, and the black matrix 380 can be disposed inside the hole.

A transparent insulating layer 390 can be disposed on the black matrix 380 in the display area.

The transparent insulating layer 390 can be disposed on the second window 370b.

The transparent insulating layer 390 can protect structures disposed below the transparent insulating layer 390. For example, the transparent insulating layer 390 can be composed of an organic insulating material, but embodiments of the present disclosure are not limited thereto. For example, the transparent insulating layer 390 can be made of a photoresist or a photoacrylic-based material, but embodiments of the present disclosure are not limited thereto. The transparent insulating layer 390 can be an overcoating layer, but embodiments of the present disclosure are not limited thereto.

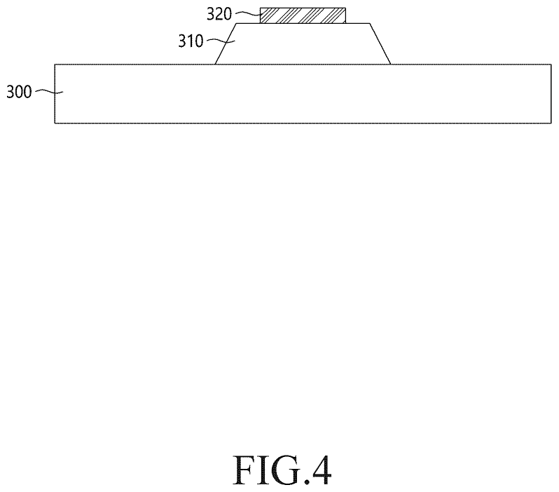

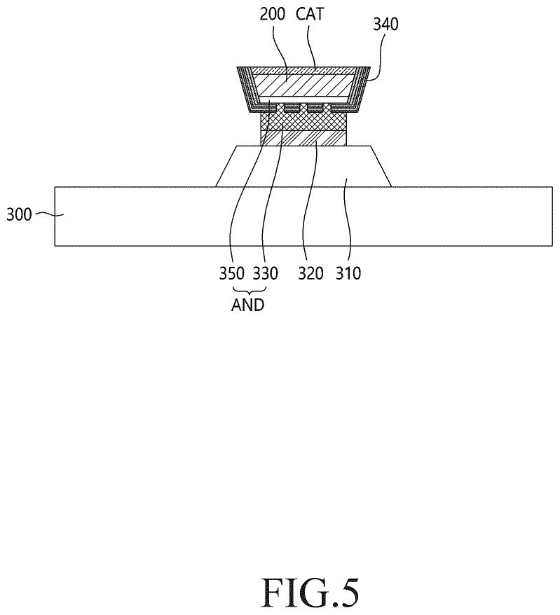

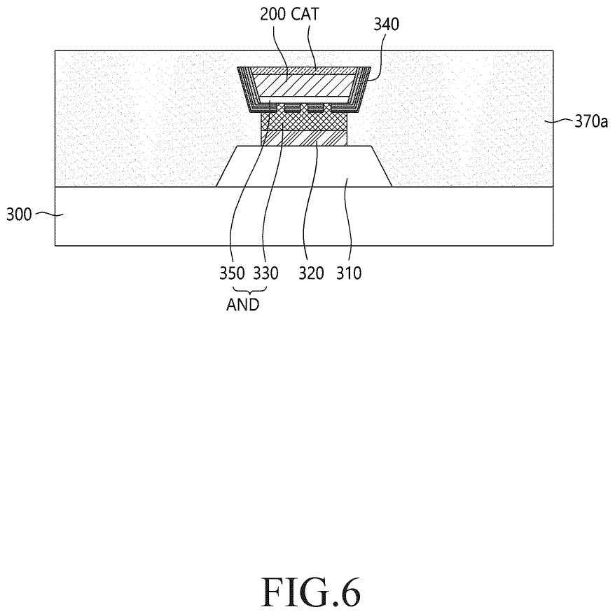

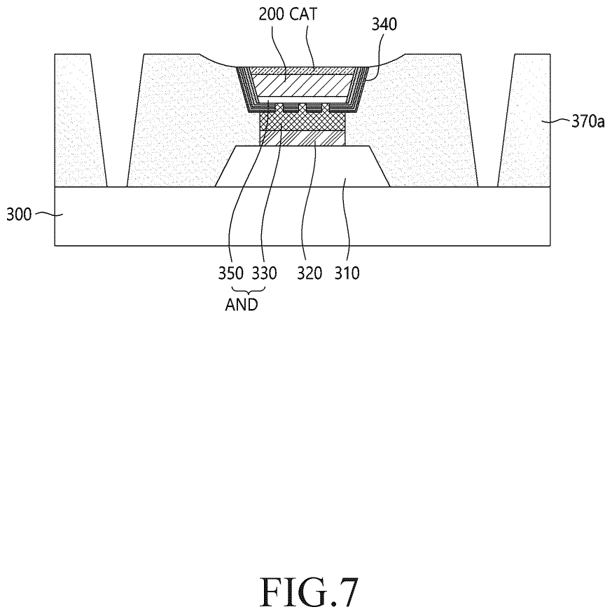

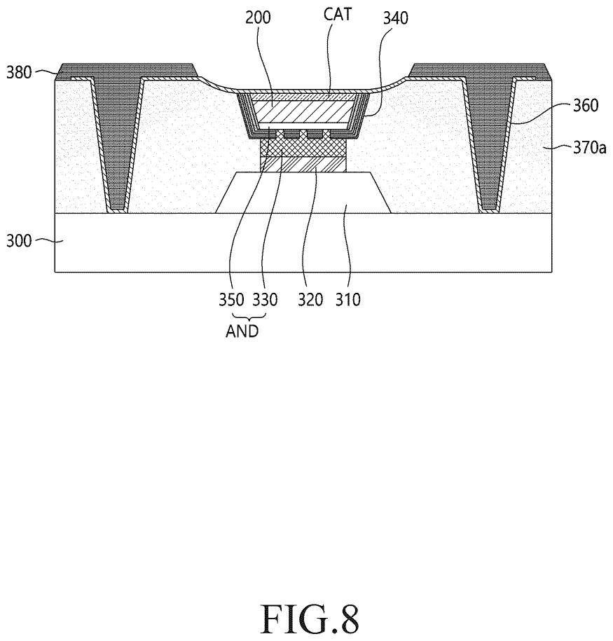

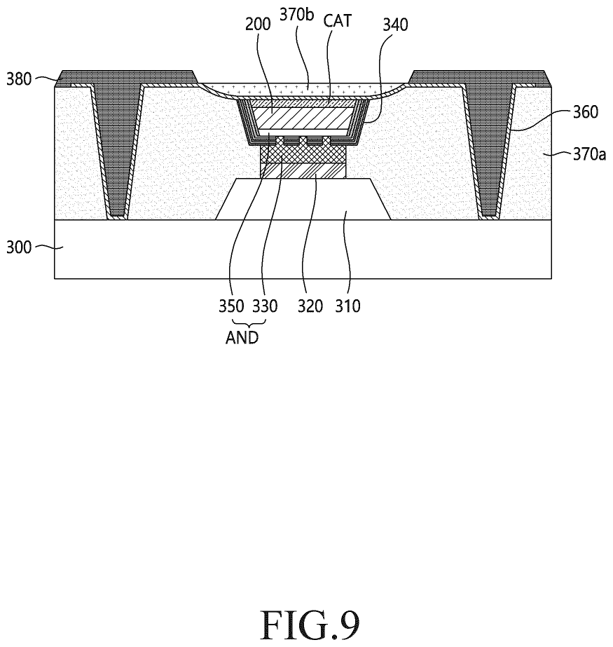

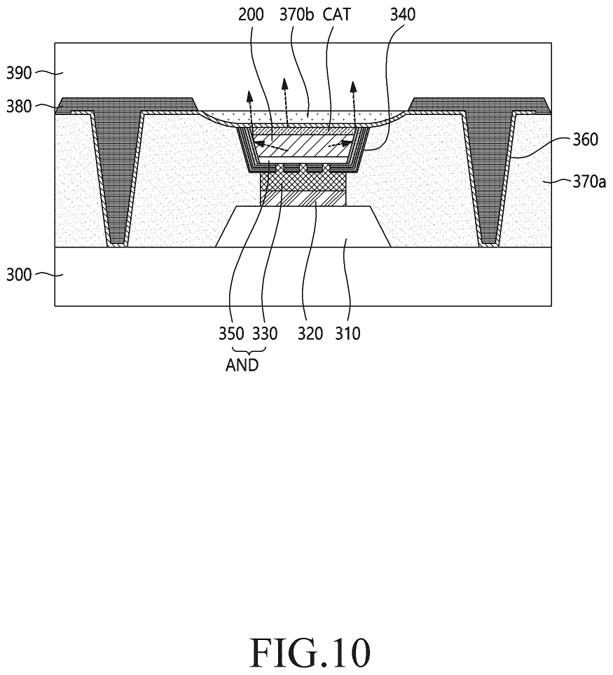

FIG. 4 to FIG. 10 illustrate manufacturing processes of the display panel 110 according to embodiments of the present disclosure.

Referring to FIG. 4 to FIG. 10, the method of manufacturing the display apparatus 100 according to embodiments of the present disclosure can include a step of disposing a bank 310 on a substrate 300; a step of disposing a first electrode 320 on the bank 310; a step of disposing a light-emitting device ED on the first electrode 320; and a step of disposing a second electrode 360 on the light-emitting device ED. Here, the steps can also be referred to as operations, processes, etc.

The light-emitting device ED can include an anode electrode AND disposed on the first electrode 320, an intermediate layer 200 disposed on the anode electrode AND, and a cathode electrode CAT disposed on the intermediate layer 200.

The anode electrode AND can include a first anode electrode 330 disposed on the first electrode 320; a second anode electrode 350 disposed on the first anode electrode 330; and an inorganic reflective layer 340 disposed between the first anode electrode 330 and the second anode electrode 350, extending along the side surface of the intermediate layer 200 and surrounding the side surface of the intermediate layer 200, and having at least one hole for electrical connection between the first anode electrode 330 and the second anode electrode 350.

The first anode electrode 330 can include a connection portion inserted inside the hole of the inorganic reflective layer 340.

According to embodiments of the present disclosure, the first electrode 320 and the first anode electrode 330 can be electrically connected through eutectic bonding. For example, when the first electrode 320 is made of indium and the first anode electrode 330 of the light-emitting device ED is made of gold, the first electrode 320 and the first anode electrode 330 can be bonded by applying heat and pressure during the transfer process of the light-emitting device ED. In addition to heat and pressure, laser bonding can also be used. Through eutectic bonding, the first electrode 320 can be bonded to the first anode electrode 330 without using a separate adhesive. For example, the first electrode 320 can be composed of indium (In), tin (Sn), or an alloy thereof, but embodiments of the present disclosure are not limited thereto. For example, the first electrode 320 can be a bonding pad or a joining pad, but embodiments of the present disclosure are not limited thereto.

The method of manufacturing the display apparatus 100 according to embodiments of the present disclosure can further include a step of disposing a first window 370a surrounding the bank 310 and the light-emitting device ED.

The first window 370a can be disposed to cover the bank 310 below the light-emitting device ED in the area of the sub-pixel. The first window 370a can cover the region between the bank 310 and the light-emitting device ED.

The first window 370a can have a hole surrounding the light-emitting device ED.

The first window 370a may not include light scattering particles. The first window 370a can be composed of an organic insulating material, but embodiments of the present disclosure are not limited thereto.

The method of manufacturing the display apparatus 100 according to embodiments of the present disclosure can further include a step of disposing the second electrode 360 on the light-emitting device ED and the first window 370a. At least a portion of the second electrode 360 can be disposed between the first window 370a and the black matrix 380 and can extend along the side surface inside the hole of the first window 370a.

The method of manufacturing the display apparatus 100 according to embodiments of the present disclosure can further include a step of disposing a black matrix 380 on the first window 370a without overlapping the light-emitting device ED.

The black matrix 380 can be disposed inside the hole of the first window 370a. The black matrix 380 can be disposed on the second electrode 360.

The second electrode 360 can be disposed between the first window 370a and the black matrix 380.

The method of manufacturing the display apparatus 100 according to embodiments of the present disclosure can further include a step of disposing a second window 370b on the second electrode 360.

The second window 370b can include light scattering particles. The second window 370b can include an organic insulating material in which fine particles are dispersed, but embodiments of the present disclosure are not limited thereto. For example, the second window 370b can be composed of siloxane in which fine metal particles such as titanium dioxide (TiO₂) particles are dispersed, but embodiments of the present disclosure are not limited thereto.

According to embodiments of the present disclosure, light from the light-emitting device ED can be scattered by the fine particles dispersed in the second window 370b and emitted to the outside of the display apparatus 100. Accordingly, the second window 370b can uniformly mix the light emitted from the light-emitting device ED, thereby further improving the luminance uniformity of the display apparatus 100. In addition, light extraction of the display apparatus 100 can be improved by light scattered from the plurality of fine particles, and thus the display apparatus 100 can be driven at lower power.

The second window 370b can be composed of a different material from the first window 370a, but embodiments of the present disclosure are not limited thereto. For example, the second window 370b can include fine particles, whereas the first window 370a may not include fine particles. In another example, the second window 370b can be composed of the same material as the first window 370a.

The thickness of the second window 370b can be smaller than the thickness of the first window 370a. When viewed in plan view, the region where the first window 370a is disposed can include a recess recessed inward relative to the top surface of the second window 370b.

The method of manufacturing the display apparatus 100 according to embodiments of the present disclosure can further include a step of disposing a transparent insulating layer 390 on the black matrix.

The transparent insulating layer 390 can be disposed on the second window 370b.

The transparent insulating layer 390 can protect the structures disposed below the transparent insulating layer 390. For example, the transparent insulating layer 390 can be composed of an organic insulating material, but embodiments of the present disclosure are not limited thereto. For example, the transparent insulating layer 390 can be made of a photoresist or a photoacrylic-based material, but embodiments of the present disclosure are not limited thereto. The transparent insulating layer 390 can be an overcoating layer, but embodiments of the present disclosure are not limited thereto.

The display apparatus and the method of manufacturing the display apparatus according to embodiments of the present disclosure can be described as follows.

The display apparatus according to embodiments of the present disclosure can include a substrate; a bank disposed on the substrate; a first electrode disposed on the bank; a light-emitting device disposed on the first electrode; and a second electrode disposed on the light-emitting device, wherein the light-emitting device can include an anode electrode disposed on the first electrode; an intermediate layer disposed on the anode electrode; and a cathode electrode disposed on the intermediate layer, and wherein the anode electrode can include a first anode electrode disposed on the first electrode; a second anode electrode disposed on the first anode electrode; and an inorganic reflective layer disposed between the first anode electrode and the second anode electrode, extending along a side surface of the intermediate layer to surround the side surface of the intermediate layer, and having at least one hole for electrical connection between the first anode electrode and the second anode electrode.

The display apparatus according to embodiments of the present disclosure can further include a first window surrounding the bank and the light-emitting device.

The first window may not include light scattering particles.

The display apparatus according to embodiments of the present disclosure can further include a black matrix disposed on the first window without overlapping the light-emitting device, wherein the first window can have a hole surrounding the light-emitting device, and the black matrix can be disposed inside the hole of the first window.

The display apparatus according to embodiments of the present disclosure can further include a second electrode disposed on the light-emitting device and the first window, wherein the second electrode can be disposed between the first window and the black matrix and can extend along a side surface inside the hole of the first window.

The display apparatus according to embodiments of the present disclosure can further include a second window disposed on the second electrode. The second window can include light scattering particles.

The display apparatus according to embodiments of the present disclosure can further include a transparent insulating layer disposed on the black matrix.

The first anode electrode can include a connection portion inserted inside the hole of the inorganic reflective layer. The first electrode can include at least one selected from indium, tin, or an indium-tin alloy.

The first anode electrode can include gold. The second anode electrode can include a transparent electrode. The inorganic reflective layer can be formed of a plurality of inorganic layers. The inorganic reflective layer can be non-conductive.

The method of manufacturing a display apparatus according to embodiments of the present disclosure can include disposing a bank on a substrate; disposing a first electrode on the bank; disposing a light-emitting device on the first electrode; and disposing a second electrode on the light-emitting device, wherein the light-emitting device can include an anode electrode disposed on the first electrode; an intermediate layer disposed on the anode electrode; and a cathode electrode disposed on the intermediate layer, and wherein the anode electrode can include a first anode electrode disposed on the first electrode; a second anode electrode disposed on the first anode electrode; and an inorganic reflective layer disposed between the first anode electrode and the second anode electrode, extending along a side surface of the intermediate layer to surround the side surface of the intermediate layer, and having at least one hole for electrical connection between the first anode electrode and the second anode electrode.

The method of manufacturing a display apparatus according to embodiments of the present disclosure can further include disposing a first window surrounding the bank and the light-emitting device.

The method of manufacturing a display apparatus according to embodiments of the present disclosure can further include disposing a black matrix on the first window without overlapping the light-emitting device, wherein the first window can have a hole surrounding the light-emitting device, and the black matrix can be disposed inside the hole of the first window.

The method of manufacturing a display apparatus according to embodiments of the present disclosure can further include disposing a second electrode on the light-emitting device and the first window, wherein the second electrode can be disposed between the first window and the black matrix and can extend along a side surface inside the hole of the first window.

The method of manufacturing a display apparatus according to embodiments of the present disclosure can further include disposing a second window on the second electrode.

The method of manufacturing a display apparatus according to embodiments of the present disclosure can further include disposing a transparent insulating layer on the black matrix.

The first anode electrode and the second anode electrode can be electrically connected through eutectic bonding.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

### DESCRIPTION OF REFERENCE NUMERALS

100: Display apparatus
110: Display panel
120: Gate driving circuit
130: Data driving circuit

What is claimed is:

1. A display apparatus comprising:
a bank disposed on a substrate;
a first electrode disposed on the bank;
a light-emitting device disposed on the first electrode; and
a second electrode disposed on the light-emitting device,
wherein the light-emitting device comprises:
an anode electrode disposed on the first electrode;
an intermediate layer disposed on the anode electrode; and
a cathode electrode disposed on the intermediate layer, and
wherein the anode electrode comprises:
a first anode electrode disposed on the first electrode;
a second anode electrode disposed on the first anode electrode; and
an inorganic reflective layer disposed between the first anode electrode and the second anode electrode, extending along a side surface of the intermediate layer to surround the side surface of the intermediate layer, and having at least one hole for electrical connection the first anode electrode and the second anode electrode.

2. The display apparatus according to claim 1, further comprising a first window surrounding the bank and the light-emitting device.

3. The display apparatus according to claim 2, further comprising a black matrix disposed on the first window and not overlapping the light-emitting device,
wherein the first window has a hole surrounding the light-emitting device, and
wherein the black matrix is disposed inside the hole of the first window.

4. The display apparatus according to claim 3, further comprising a second electrode disposed on the light-emitting device and the first window,
wherein the second electrode is disposed between the first window and the black matrix and extends along a side surface inside the hole of the first window.

5. The display apparatus according to claim 4, further comprising a second window disposed on the second electrode.

6. The display apparatus according to claim 5, wherein the second window comprises light scattering particles.

7. The display apparatus according to claim 3, further comprising a transparent insulating layer disposed on the black matrix.

8. The display apparatus according to claim 1, wherein the first anode electrode comprises a connection portion inserted inside the at least one hole of the inorganic reflective layer.

9. The display apparatus according to claim 1, wherein the first electrode comprises at least one selected from indium, tin, and an indium-tin alloy.

10. The display apparatus according to claim 1, wherein the first anode electrode comprises gold.

11. The display apparatus according to claim 1, wherein the second anode electrode comprises a transparent electrode.

12. The display apparatus according to claim 1, wherein the inorganic reflective layer comprises a plurality of inorganic layers.

13. The display apparatus according to claim 1, wherein the inorganic reflective layer is non-conductive.

14. A method of manufacturing a display apparatus, the method comprising:
disposing a bank on a substrate;
disposing a first electrode on the bank;
disposing a light-emitting device on the first electrode; and
disposing a second electrode on the light-emitting device,
wherein the light-emitting device comprises:
an anode electrode disposed on the first electrode;
an intermediate layer disposed on the anode electrode; and
a cathode electrode disposed on the intermediate layer,
wherein the anode electrode comprises:
a first anode electrode disposed on the first electrode;
a second anode electrode disposed on the first anode electrode; and
an inorganic reflective layer disposed between the first anode electrode and the second anode electrode, extending along a side surface of the intermediate layer to surround the side surface of the intermediate layer, and having at least one hole for electrical connection between the first anode electrode and the second anode electrode.

15. The method of manufacturing the display apparatus according to claim 14, further comprising disposing a first window surrounding the bank and the light-emitting device.

16. The method of manufacturing the display apparatus according to claim 15, further comprising disposing a black matrix on the first window and not overlapping the light-emitting device,
wherein the first window has a hole surrounding the light-emitting device, and
wherein the black matrix is disposed inside the hole of the first window.

17. The method of manufacturing the display apparatus according to claim 16, further comprising disposing a second electrode on the light-emitting device and the first window,
wherein the second electrode is disposed between the first window and the black matrix and extends along a side surface inside the hole of the first window.

18. The method of manufacturing the display apparatus according to claim 17, further comprising disposing a second window on the second electrode.

19. The method of manufacturing the display apparatus according to claim 16, further comprising disposing a transparent insulating layer on the black matrix.

20. The method of manufacturing a display apparatus according to claim 14, wherein the first anode electrode and the second anode electrode are electrically connected through eutectic bonding.
